(19) United States
(12) Patent Application Publication
(10) Pub. No.: US 2008/0197364 A1
(43) Pub. Date: Aug. 21, 2008

(54) Light-emitting device

(75) Inventors: Ching-Huei Wu, San Chung City (TW); Tung-Ching Wu, San Chung City (TW)

Correspondence Address: TROXELL LAW OFFICE PLLC, SUITE 1404, 5205 LEESBURG PIKE, FALLS CHURCH, VA, 22041, US

(73) Assignee: Unity Opto Technology Co., Ltd.

(21) Appl. No.: 11/783,277

(22) Filed: Apr. 6, 2007

(30) Foreign Application Priority Data
Feb. 15, 2007 (TW) 096105651

(51) Int. Cl. H01L 33/00

(52) U.S. Cl. 257/89; 257/E33.061

(57) ABSTRACT

A light-emitting device comprises a support frame and at least one blue light-emitting chip and at least one red light-emitting chip coupled onto the support frame; and a green phosphor covering the at least one blue light-emitting chip and the at least one red light-emitting chip. The green phosphor is mainly an aluminate of the formula: M_{1.x}EuₓAl_{y}O_{1+3y/2}, wherein M is at least one divalent metal selected from a group consisting of Ba, Sr, Ca, Mg, Mn, Zn, Cu, Cd, Sm and Tm; 0.1<x<0.9; and 0.5≦y≦12, whereby the light beams emitted from the blue light-emitting chip and the red light-emitting chip are allowed to pass through the green phosphor for generating white light.

### FIELD OF THE INVENTION

The present invention relates to a light-emitting device, and more particularly a light-emitting diode that allows the light beams emitted from a blue light-emitting chip and a red light-emitting chip to pass through a green phosphor for generating the white light.

### BACKGROUND OF THE INVENTION

Most light-emitting diodes emit monochromic light such as red light, green light, blue light, etc. At least two light beams of different colors (wavelengths) must be mixed with each other to produce the white light visually observable by human eyes. For example, three primary colors (red, green and blue) can be mixed with one another to form the white color. Alternatively, the white color can be produced by mixing complementary colors such as blue and yellow colors or cyan and red colors.

According to the same principle, the red, green and blue light-emitting chips and different excitation currents can be used simultaneously so that respective primary-color light beams can be mixed for producing the white light. As shown in FIG. 4, in this white light LED, the red, blue and green light-emitting chips A1, A2 and A3 are packaged in a package C, and a control chip E is also packaged thereinto. These three light-emitting chips A1, A2 and A3 are connected to the leading wires of the control chip E by respective chip wires B. The pins D are designed for coupling with the outside.

However, the above-mentioned structure must equip with the red, blue and green light-emitting chips simultaneously. Therefore, it is high in cost and not easy to manufacture. In addition, the white light is generated only on the overlap among these three light-emitting chips. In view of the above-mentioned drawbacks, the present inventor makes diligent studies in providing general public with a light-emitting device, which is high in cost, low in brightness, and easy to practice.

### SUMMARY OF THE INVENTION

It is a primary object of the present invention to provide a light-emitting diode that allows the light beams emitted from the blue light-emitting chip and the red light-emitting chip to pass through the green phosphor for generating the white light. As a result, the cost for producing the white light LED can be reduced and the brightness of the white light can be increased, thereby increasing the entire practicability.

It is a secondary object of the present invention to provide a light-emitting diode that allows the light beam emitted from the blue light-emitting chip to pass through the green phosphor for generating the white light. As a result, the cost for producing the white light LED can be reduced and the brightness of the white light can be increased, thereby increasing the entire convenience and practicability.

In order to achieve the foregoing objects, a light-emitting device comprises a support frame and at least one blue light-emitting chip and at least one red light-emitting chip coupled onto the support frame; and a green phosphor covering the at least one blue light-emitting chip and the at least one red light-emitting chip. The green phosphor is mainly an aluminate of the formula: M_{1.x}EuₓAl_{y}O_{1+3y/2}, wherein M is at least one divalent metal selected from a group consisting of Ba, Sr, Ca, Mg, Mn, Zn, Cu, Cd, Sm and Tm; 0.1<x<0.9; and 0.5≦y≦12, whereby the light beams emitted from the blue light-emitting chip and the red light-emitting chip are allowed to pass through the green phosphor to generate the white light.

The aforementioned and other objects and advantages of the present invention will be readily clarified in the description of the preferred embodiments and the enclosed drawings of the present invention.

### BRIEF DESCRIPTION OF THE DRAWINGS

FIG. 1 is a cross-sectional view showing a first embodiment of the present invention.

FIG. 2 is a cross-sectional view showing a second embodiment of the present invention.

FIG. 3 is a cross-sectional view showing a third embodiment of the present invention.

FIG. 4 is a top view showing a white light LED of prior art.

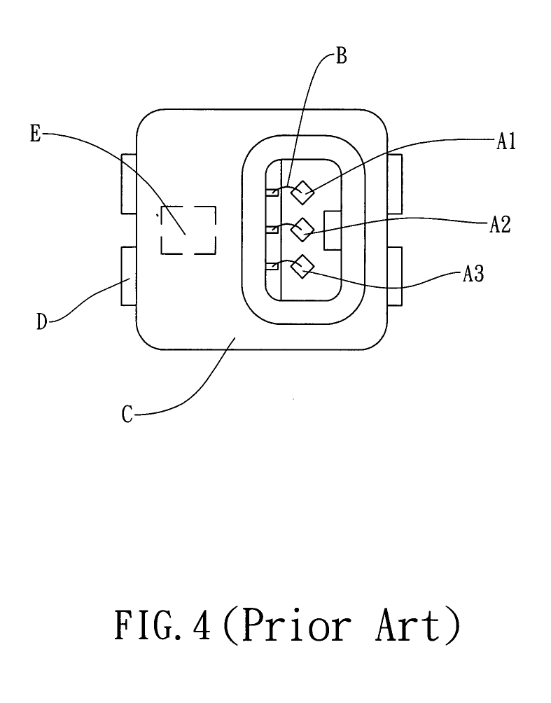

### DETAILED DESCRIPTION OF THE PREFERRED EMBODIMENT

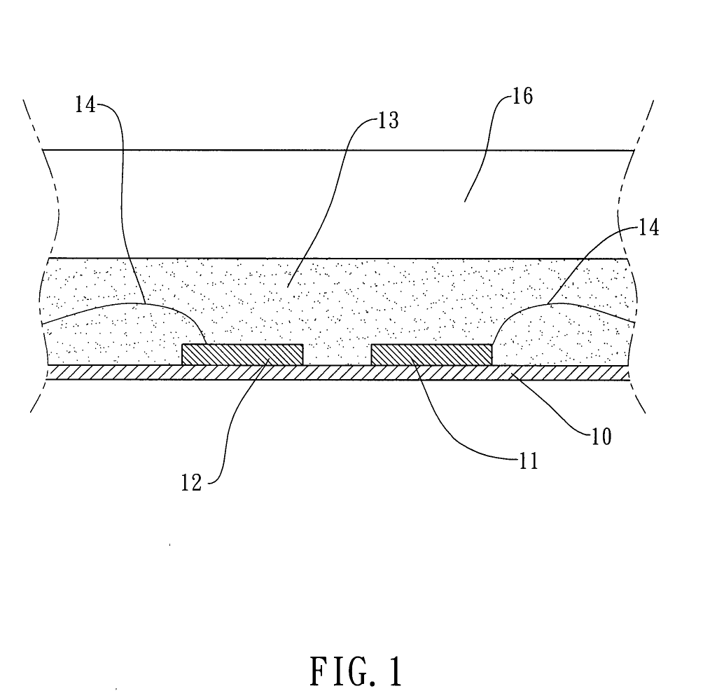

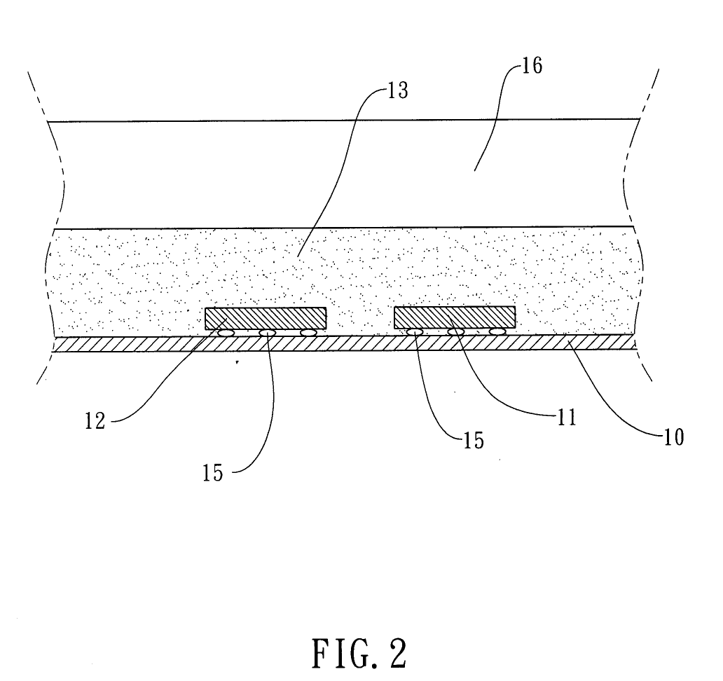

Referring to FIGS. 1 and 2, a light-emitting device of the present invention generally comprises at least one blue light-emitting chip 11 and at least one red light-emitting chip 12 coupled onto a support frame 10, wherein the blue light-emitting chip 11 and the red light-emitting chip 12 have respective conducting wires 14 for connection with the support frame 10 or other pins (not shown). In addition, the blue light-emitting chip 11 and the red light-emitting chip 12 are covered with a green phosphor 13. The green phosphor 13 is mainly an aluminate of the formula: M_{1.x}EuₓAl_{y}O_{1+3y/2}, wherein M is at least one divalent metal selected from a group consisting of Ba, Sr, Ca, Mg, Mn, Zn, Cu, Cd, Sm and Tm; 0.1<x<0.9; and 0.5≦y≦12. The light beams emitted from the blue light-emitting chip 11 and red light-emitting chip 12 are allowed to pass through the green phosphor 13 to generate the white light instead of mixing three primary-color light beams emitted from red, blue and green light-emitting chips. Therefore, the cost for producing the white-light LED can be reduced and the brightness of the white light can be increased. Referring again to FIG. 2, the blue light-emitting chip 11 and the red light-emitting chip 12 can be coupled onto the support frame 10 in a flip-chip configuration by tin or gold solder balls. For example, in the illustrated embodiment, the blue light-emitting chip 11 and the red light-emitting chip 12 are flip-chip coupled onto the support frame 10 by several tin solder balls 15.

Referring to FIGS. 1 and 2, the light beams emitted from the blue light-emitting chip 11 and red light-emitting chip 12 are allowed to pass through the green phosphor 13 to emit the white light. The green phosphor 13 is mainly an aluminate of the formula: M_{1.x}EuₓAl_{y}O_{1+3y/2}, wherein M is at least one divalent metal selected from a group consisting of Ba, Sr, Ca, Mg, Mn, Zn, Cu, Cd, Sm and Tm; 0.1<x<0.9; and 0.5≦y≦12. Accordingly, there is no need to employ the green light-emitting chip, whereby the cost for producing the white light can be reduced. The white light generated by the present invention has a higher brightness than the white light obtained by mixing three primary-color light beams emitted from red, blue and green light-emitting chips. Besides, the blue light-emitting chip 11 and the red light-emitting chip 12 are coupled onto the support frame 10 in the flip-chip configuration.

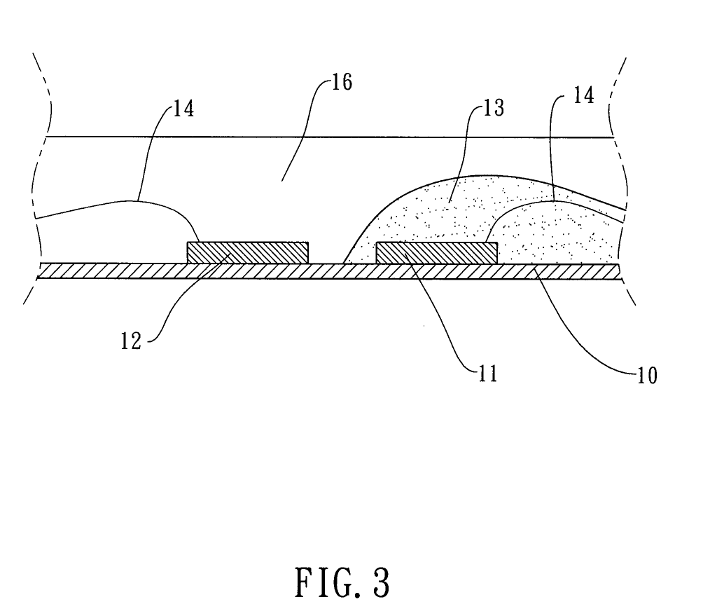

Referring further to FIG. 3, in practical use, only the blue light-emitting chip 11 is covered with the green phosphor 13, and a transparent layer 16 is employed for sealing and positioning, wherein the blue light-emitting chip 11 and the red light-emitting chip 12 can be connected to the support frame 10 or other pins via respective conducting wires 14 or flip-chip connected thereto directly. Therefore, the light beams emitted from the blue light-emitting chip 11 can pass through the green phosphor 13 to be mixed with the light beams emitted from the red light-emitting chip 12 for generating the white light.

In accordance with the foregoing description, the present invention has the following practical advantages:

1. The light beams emitted from the blue light-emitting chip and red light-emitting chip are allowed to pass through the green phosphor to generate the white light, and the green phosphor is mainly an aluminate so there is no need to employ the green light-emitting chip, whereby the cost for producing the white light can be reduced and the produced white light has a higher brightness.

2. Optionally, only the blue light-emitting chip is covered with the green phosphor in such a manner that the light beam emitted from the blue light-emitting chip can pass through the green phosphor to be mixed with the light beam emitted from the red light-emitting chip for generating the white light, thereby providing more flexibility in generating the white light.

To sum up, the present invention achieves the anticipated objects. The present invention discloses a light-emitting device capable of reducing cost and increasing brightness, and it is easy to practice. Therefore, this application is filed according to the patent law.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments, which do not depart from the spirit and scope of the invention.

What the invention claimed is:

1. A light-emitting device, comprising:
a support frame;
at least one blue light-emitting chip and at least one red light-emitting chip coupled onto said support frame; and
a green phosphor covering said at least one blue light-emitting chip and said at least one red light-emitting chip, wherein said green phosphor is mainly an aluminate of the formula: M_{1.x}EuₓAl_{y}O_{1+3y/2}, and wherein M is at least one divalent metal selected from a group consisting of Ba, Sr, Ca, Mg, Mn, Zn, Cu, Cd, Sm and Tm; 0.1<x<0.9; and 0.5≦y≦12, whereby two respective light beams emitted from said at least one blue light-emitting chip and said at least one red light-emitting chip are allowed to pass through said green phosphor to generate white light.

2. A light-emitting device of claim 1, wherein said at least one blue light-emitting chip and said at least one red light-emitting chip are coupled onto said support frame in a flip-chip configuration.

3. A light-emitting device of claim 1, further comprising a transparent layer disposed on said support frame.

4. A light-emitting device, comprising:
a support frame;
at least one blue light-emitting chip and at least one red light-emitting chip coupled onto said support frame; and
a green phosphor covering said at least one blue light-emitting chip, wherein said green phosphor is mainly an aluminate of the formula: M_{1.x}EuₓAl_{y}O_{1+3y/2}, and wherein M is at least one divalent metal selected from a group consisting of Ba, Sr, Ca, Mg, Mn, Zn, Cu, Cd, Sm and Tm; 0.1<x<0.9; and 0.5≦y≦12, whereby a light beam emitted from said at least one blue light-emitting chip are allowed to pass through said green phosphor to be mixed with a light beam emitted from said at least one red light-emitting chip for generating white light.

5. A light-emitting device of claim 4, wherein said at least one blue light-emitting chip and said at least one red light-emitting chip are coupled onto said support frame in a flip-chip configuration.

6. A light-emitting device of claim 4, further comprising a transparent layer disposed on said support frame.
